(19) United States
(12) Patent Application Publication
(10) Pub. No.: US 2025/0254061 A1
(43) Pub. Date: Aug. 7, 2025

(54) COMMUNICATION SYSTEM, CALCULATION DEVICE, AND COMMUNICATION METHOD

(71) Applicant: Tokyo Electron Limited, Tokyo (JP)

(72) Inventor: Motoki TOKAIRIN, Miyagi (JP)

(73) Assignee: Tokyo Electron Limited, Tokyo (JP)

(21) Appl. No.: 19/092,034

(22) Filed: Mar. 27, 2025

Related U.S. Application Data
(63) Continuation of application No. PCT/JP2023/029639, filed on Aug. 16, 2023.

(30) Foreign Application Priority Data
Sep. 28, 2022 (JP) 2022-154754

(51) Int. Cl. H04L 12/28

(52) U.S. Cl. CPC H04L 12/28

(57) ABSTRACT

A communication system includes: a main device; a plurality of subordinate devices communicatively connected to the main device; and a calculation device communicatively connected to the main device and the subordinate devices, wherein a data frame transmitted to the plurality of subordinate devices includes a plurality of datagrams for each of the plurality of subordinate devices, each of the plurality of datagrams including setting data for a corresponding one of the plurality of subordinate devices and monitor data to be written in the corresponding one of the plurality of subordinate devices, and wherein the calculation device is configured to obtain, based on the monitor data for each of the plurality of subordinate devices in the data frame received in a preceding communication cycle, updated setting data for each of the plurality of datagrams in the data frame transmitted to the plurality of subordinate devices in a subsequent communication cycle.

### CROSS-REFERENCE TO RELATED APPLICATIONS

The application is a Bypass Continuation application of PCT International Application No. PCT/JP2023/029639, filed on Aug. 16, 2023 and designating the United States, the international application being based upon and claiming the benefit of priority from Japanese Patent Application No. 2022-154754, filed on Sep. 28, 2022, the entire contents of each are incorporated herein by reference.

### TECHNICAL FIELD

Exemplary embodiments of the present disclosure relate to a communication system, a calculation device, and a communication method.

### BACKGROUND

In industrial systems, EtherCAT (registered trademark), which is an industrial Ethernet (registered trademark), is used as a protocol for data communication. In an industrial system conforming to EtherCAT, a main device (primary device or master device) and a plurality of subordinate devices (secondary devices or slave devices) are connected with each other. The main device transmits a data frame including setting data for each of the plurality of subordinate devices to the plurality of subordinate devices. The setting data for each of the plurality of subordinate devices is obtained in the main device.

### PRIOR ART DOCUMENT

### Patent Document

Patent Document 1: Japanese Patent Laid-open Publication No. 2010-278897

### SUMMARY

One embodiment of the present disclosure provides a communication system. The communication system includes a main device, a plurality of subordinate devices, and a calculation device. The plurality of subordinate devices are communicatively connected to the main device. The calculation device is communicatively connected to the main device and the plurality of subordinate devices. A data frame transmitted to the plurality of subordinate devices includes a plurality of datagrams for each of the plurality of subordinate devices. Each of the plurality of datagrams includes setting data for a corresponding one of the plurality of subordinate devices and monitor data to be written in the corresponding one of the plurality of subordinate devices. The calculation device is configured to obtain, based on the monitor data for each of the plurality of subordinate devices in the data frame received in a preceding communication cycle, updated setting data for each of the plurality of datagrams in the data frame transmitted to the plurality of subordinate devices in a subsequent communication cycle.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining a configuration example a plasma processing system.

FIG. 2 is a diagram for explaining a configuration example of a capacitively coupled plasma processing apparatus.

FIG. 3 is a diagram showing a plasma processing system according to an exemplary embodiment.

FIG. 4 is a diagram showing a communication system according to an exemplary embodiment.

FIG. 5 is a diagram showing an example of a data frame.

FIG. 6 is a diagram showing a calculation device according to an exemplary embodiment.

FIG. 7 is a flowchart of a communication method according to an exemplary embodiment.

FIG. 8 is a diagram showing a flow of a first data frame in the communication system according to an exemplary embodiment.

FIG. 9 is a diagram showing a flow of a second data frame in the communication system according to an exemplary embodiment.

FIG. 10 is a diagram showing a communication system according to another exemplary embodiment.

FIG. 11 is a diagram showing a calculation device according to another exemplary embodiment.

FIG. 12 is a flowchart of a communication method according to another exemplary embodiment.

FIG. 13 is a diagram showing a flow of a first data frame in the communication system according to another exemplary embodiment.

FIG. 14 is a diagram showing a second data frame used in the communication system according to another exemplary embodiment.

FIG. 15 is a diagram showing a flow of a second data frame in the communication system according to another exemplary embodiment.

FIG. 16 is a diagram showing a third data frame used in the communication system according to another exemplary embodiment.

FIG. 17 is a diagram showing a flow of a third data frame in the communication system according to another exemplary embodiment.

FIG. 18 is a diagram showing a flow of a fourth data frame in the communication system according to another exemplary embodiment.

FIG. 19 is a diagram showing another flow of the first data frame in the communication system according to the exemplary embodiment.

FIG. 20 is a diagram showing another flow of the second data frame in the communication system according to the exemplary embodiment.

FIG. 21 is a diagram showing another flow of the first data frame in the communication system according to the another exemplary embodiment.

FIG. 22 is a diagram showing another flow of the fourth data frame in the communication system according to the another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Various exemplary embodiments will be described in detail below with reference to the drawings. Note that the same or equivalent parts in the drawings are denoted by the same reference numerals.

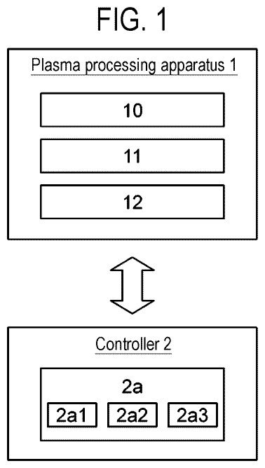

First, a plasma processing system will be described as an example of a communication system with reference to FIGS. 1 to 3.

FIG. 1 is a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma process chamber 10, a substrate support 11, and a plasma generator 12. The plasma process chamber 10 has a plasma processing space. The plasma process chamber 10 also has at least one gas supply port for supplying at least one process gas into the plasma processing space, and at least one gas discharge port for discharging a gas from the plasma processing space. The gas supply port is connected to a gas supply 20 to be described later, and the gas discharge port is connected to an exhaust system 40 to be described later. The substrate support 11 is disposed in the plasma processing space and has a substrate support surface for supporting a substrate.

The plasma generator 12 is configured to generate plasma from at least one process gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), and the like. In addition, various types of plasma generators may be used, including an alternating current (AC) plasma generator and a direct current (DC) plasma generator. In one embodiment, an AC signal (AC power) used in the AC plasma generator has a frequency within a range of 100 kHz to 10 GHz. Thus, the AC signal includes a radio frequency (RF) signal and a microwave signal. In one embodiment, the RF signal has a frequency within a range of 100 kHz to 150 MHz.

The controller 2 processes computer-executable instructions that cause the plasma processing apparatus 1 to perform various steps to be described in the present disclosure. The controller 2 can be configured to control individual components of the plasma processing apparatus 1 to perform the various steps to be described herein. In one embodiment, a part or all of the controller 2 may be included in the plasma processing apparatus 1. The controller 2 may include a processor 2a1, a storage 2a2, and a communication interface 2a3. The controller 2 is implemented by, for example, a computer 2a. The processor 2a1 can be configured to read a program from the storage 2a2 and execute the read program to perform various control operations. This program may be stored in the storage 2a2 in advance, or may be acquired via a medium when necessary. The acquired program is stored in the storage 2a2, and is read and executed from the storage 2a2 by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

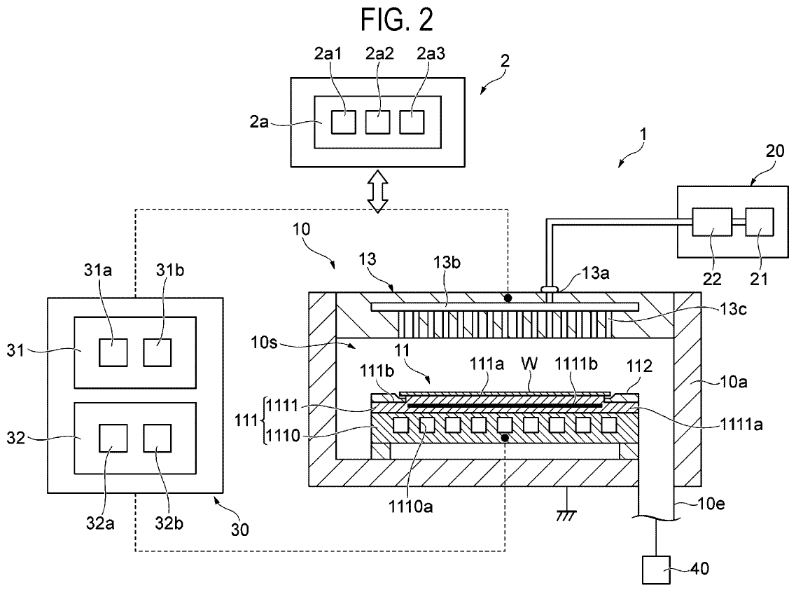

Below, a configuration example of a capacitively coupled plasma processing apparatus as an example of the plasma processing apparatus 1 will be described. FIG. 2 is a diagram for explaining a configuration example of a capacitively coupled plasma processing apparatus.

The capacitively coupled plasma processing apparatus 1 includes the plasma process chamber 10, the gas supply 20, a power supply 30, and the exhaust system 40. The plasma processing apparatus 1 also includes the substrate support 11 and a gas introducer. The gas introducer is configured to introduce at least one process gas into the plasma process chamber 10. The gas introducer includes a showerhead 13. The substrate support 11 is disposed in the plasma process chamber 10. The showerhead 13 is disposed above the substrate support 11. In one embodiment, the showerhead 13 constitutes at least a portion of a ceiling of the plasma process chamber 10. The plasma process chamber 10 has a plasma processing space 10s defined by the showerhead 13, a sidewall 10a of the plasma process chamber 10, and the substrate support 11. The plasma process chamber 10 is grounded. The showerhead 13 and the substrate support 11 are electrically insulated from a housing of the plasma process chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 to surround the substrate W on the central region 111a of the main body 111. Therefore, the central region 111a is also called a substrate support surface for supporting the substrate W, and the annular region 111b is also called a ring support surface for supporting the ring assembly 112.

In one embodiment, the main body 111 includes a base 1110 and an electrostatic chuck 1111. The base 1110 includes a conductor. The conductor of the base 1110 can function as a lower electrode. The electrostatic chuck 1111 is disposed on the base 1110. The electrostatic chuck 1111 includes a ceramic 1111a and an electrostatic electrode 1111b disposed inside the ceramic 1111a. The ceramic 1111a has a central region 111a. In one embodiment, the ceramic 1111a also has an annular region 111b. In addition, other members surrounding the electrostatic chuck 1111, such as an annular electrostatic chuck or an annular insulator, may have the annular region 111b. In this case, the ring assembly 112 may be disposed on the annular electrostatic chuck or the annular insulator, or may be disposed on both the electrostatic chuck 1111 and the annular insulator. In addition, at least one RF/DC electrode coupled to an RF power supply 31 and/or a DC power supply 32, which will be described later, may be disposed inside the ceramic 1111a. In this case, the at least one RF/DC electrode functions as a lower electrode. When a bias RF signal and/or a DC signal, which will be described later, is supplied to the at least one RF/DC electrode, the RF/DC electrode is also called a bias electrode. In addition, the conductor of the base 1110 and the at least one RF/DC electrode may function as a plurality of lower electrodes. In addition, the electrostatic electrode 1111b may function as a lower electrode. Thus, the substrate support 11 includes at least one lower electrode.

The ring assembly 112 includes two or more annular members. In one embodiment, the two or more annular members include one or more edge rings and at least one cover ring. The edge ring is formed of a conductive material or an insulating material, and the cover ring is formed of an insulating material.

The substrate support 11 may also include a temperature adjustment module configured to adjust at least one of the electrostatic chuck 1111, the ring assembly 112, and the substrate to a target temperature. The temperature adjustment module may include a heater, a heat transfer medium, a flow passage 1110a, or a combination thereof. A heat transfer fluid such as brine or a gas flows through the flow passage 1110a. In one embodiment, the flow passage 1110a is formed in the base 1110, and one or more heaters are disposed inside the ceramic 1111a of the electrostatic chuck 1111. The substrate support 11 may also include a heat transfer gas supply configured to supply a heat transfer gas to a gap between a back surface of the substrate W and the central region 111a.

The showerhead 13 is configured to introduce at least one process gas from the gas supply 20 into the plasma processing space 10s. The showerhead 13 has at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s from the gas introduction ports 13c. The showerhead 13 also includes at least one upper electrode. The gas introducer may include, in addition to the showerhead 13, one or more side gas injectors (SGIs) attached to one or more openings formed in the sidewall 10a.

The gas supply 20 may include at least one gas source 21 and at least one flow rate controller 22. In one embodiment, the gas supply 20 is configured to supply at least one process gas from the corresponding gas source 21 to the showerhead 13 via the corresponding flow rate controller 22. Each flow rate controller 22 may include, for example, a mass flow controller or a pressure-controlled flow rate controller. Further, the gas supply 20 may include at least one flow modulation device that modulates or pulses a flow rate of at least one process gas.

The power supply 30 includes the RF power supply 31 coupled to the plasma process chamber 10 via at least one impedance matching circuit. The RF power supply 31 is configured to supply at least one RF signal (RF power) to at least one lower electrode and/or at least one upper electrode. This causes plasma to be generated from at least one process gas supplied to the plasma processing space 10s. Thus, the RF power supply 31 can function as at least a part of the plasma generator 12. In addition, by supplying a bias RF signal to at least one lower electrode, bias potential is generated on the substrate W, and ion components in the generated plasma can be attracted to the substrate W.

In one embodiment, the RF power supply 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency within a range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate a bias RF signal (bias RF power). A frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power supply 30 may also include the DC power supply 32 coupled to the plasma process chamber 10. The DC power supply 32 includes a first DC generator 32a and a second DC generator 32b. In one embodiment, the first DC generator 32a is configured to be connected to at least one lower electrode to generate a first DC signal. The generated first DC signal is applied to the at least one lower electrode. In one embodiment, the second DC generator 32b is configured to be connected to at least one upper electrode to generate a second DC signal. The generated second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may have a pulse waveform that is rectangular, trapezoidal, triangular, or a combination thereof. In one embodiment, a waveform generator for generating a sequence of voltage pulses from a DC signal is connected between the first DC generator 32a and at least one lower electrode. Thus, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have positive polarity or negative polarity. In addition, the sequence of voltage pulses may include one or more positive voltage pulses and one or more negative voltage pulses in one period. In addition, the first and second DC generators 32a and 32b may be provided in addition to the RF power supply 31, or the first DC generator 32a may be provided instead of the second RF generator 31b.

The exhaust system 40 may be connected to, for example, a gas discharge port 10e provided at a bottom of the plasma process chamber 10. The exhaust system 40 may include a pressure regulating valve and a vacuum pump. An internal pressure of the plasma processing space 10s is adjusted by the pressure regulating valve. The vacuum pump may include a turbo molecular pump, a dry pump, or a combination of these.

The plasma processing system includes a main device (primary device or master device) and a plurality of subordinate devices (secondary devices or slave devices). In the plasma processing system, data communication is performed by using a data frame conforming to EtherCAT as a communication protocol. In the plasma processing system, the main device corresponds to the controller 2.

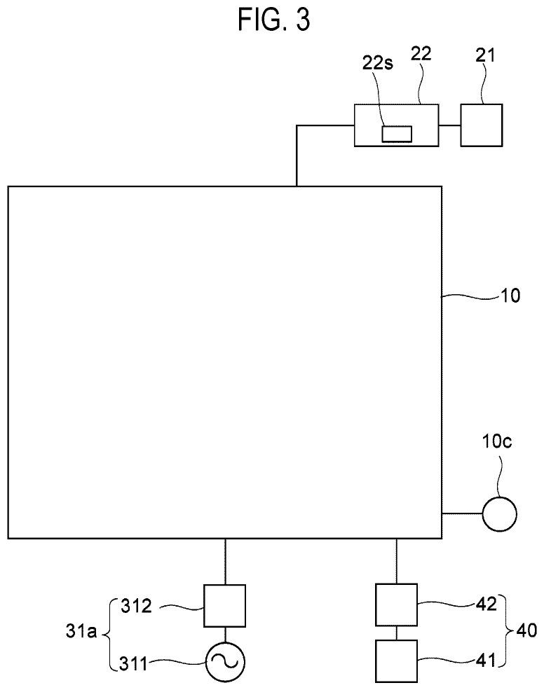

FIG. 3 is a diagram showing a plasma processing system according to an exemplary embodiment. As shown in FIG. 3, the plasma processing system may further include a pressure sensor 10c. The pressure sensor 10c is configured to acquire a measured value (example of monitor data) of an internal pressure of the chamber 10. The pressure sensor 10c is, for example, a capacitance manometer.

In addition, the exhaust system 40 may include a depressurization pump 41 and a pressure controller 42. The depressurization pump 41 may include a dry pump and/or a turbo molecular pump. The depressurization pump 41 is connected to the chamber 10 via the pressure controller 42. The pressure controller 42 is, for example, a pressure control valve. The pressure controller 42 is configured to control the internal pressure (control amount) of the chamber 10 according to setting data (pressure setting value). The plurality of subordinate devices in the plasma processing system may include the pressure sensor 10c and the pressure controller 42.

In addition, the flow rate controller 22 includes a flow rate sensor 22s. The flow rate sensor 22s is configured to acquire a measured value (another example of the monitor data) of a flow rate of a gas supplied from the flow rate controller 22 into the chamber 10. The flow rate controller 22 is configured to control the flow rate (control amount) of the gas supplied to the chamber 10 according to setting data (flow rate setting value). The plurality of subordinate devices in the plasma processing system may include the flow rate controller 22.

In addition, the first RF generator 31a may include a radio frequency power supply 311 and a sensor 312. The radio frequency power supply 311 is configured to generate a first RF signal (source radio frequency power). The sensor 312 is configured to acquire a state value of the source radio frequency power. The state value (example of the monitor data) of the source radio frequency power may be a power level of traveling waves of the source radio frequency power, a power level of reflected waves of the source radio frequency power, or a level of load power of the source radio frequency power (a difference between the power level of the traveling waves and the power level of the reflected waves). The radio frequency power supply 311 is configured to control the source radio frequency power according to setting data (setting data of the source radio frequency power). The plurality of subordinate devices in the plasma processing system may include the first RF generator 31a. In addition, the plurality of subordinate devices in the plasma processing system may include other devices in the plasma processing system other than the controller 2.

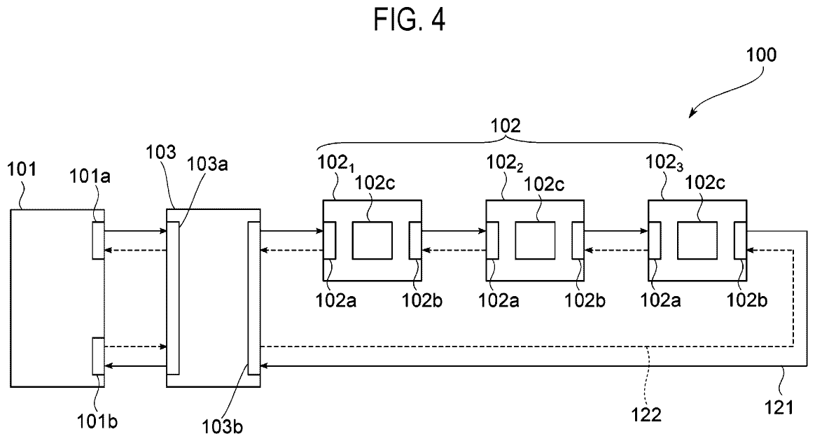

Below, a communication system according to an exemplary embodiment will be described with reference to FIG. 4. The above-described plasma processing system is an example of a communication system 100 shown in FIG. 4. As shown in FIG. 4, the communication system 100 includes a main device 101, a plurality of subordinate devices 102, and a calculation device 103. The communication system 100 includes N subordinate devices 102. N is an integer equal to or greater than 2. In the illustrated example, N is 3. That is, in the illustrated example, the communication system 100 includes subordinate devices 102₁, 102₂, and 102₃ as the plurality of subordinate devices 102. In the following description, a subordinate device 102ₐ indicates any one of the plurality of subordinate devices 102.

The main device 101 is the controller 2 in the plasma processing system. The main device 101 includes a first port 101a and a second port 101b. The subordinate devices 102 are communicatively connected to the main device 101. The calculation device 103 is communicatively connected to the main device 101 and the subordinate devices 102. The subordinate devices 102 and the calculation device 103 may be connected in series to the main device 101. The communication system 100 includes a communication path 121 (main communication path). The communication path 121 is a communication path that returns from the first port 101a to the second port 101b via the calculation device 103 and the subordinate devices 102 (in one example, via a series connection of the calculation device 103 and the subordinate devices 102). In one embodiment, the communication system 100 may further include a communication path 122 (backup communication path). The communication path 122 is a communication path that returns from the second port 101b to the first port 101a via the subordinate devices 102 and the calculation device 103 (in one example, via a series connection of the subordinate devices 102 and the calculation device 103).

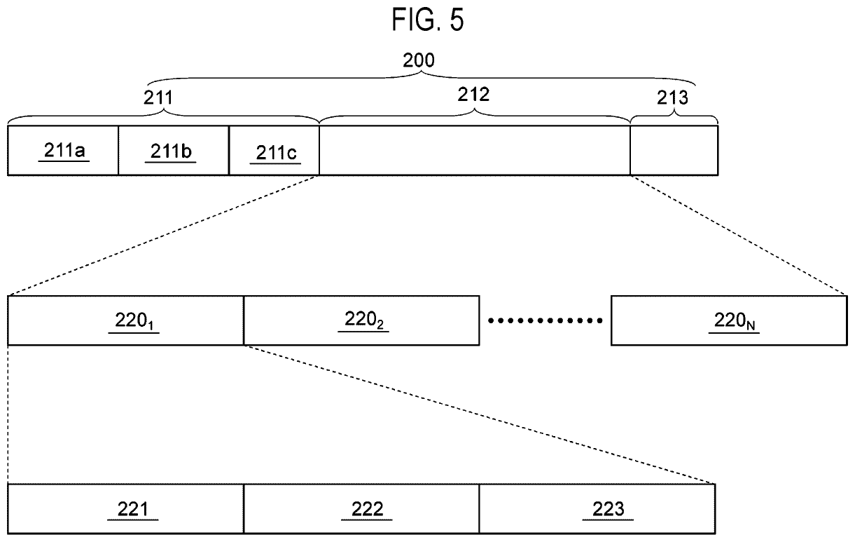

The communication system 100 performs data communication by using a data frame shown in FIG. 5. FIG. 5 is a diagram showing an example of a data frame. A data frame 200 shown in FIG. 5 is a data frame conforming to EtherCAT. The data frame 200 includes an Ethernet header 211, Ethernet data 212, and a frame check sequence 213. The Ethernet header 211 includes a destination MAC address 211a, a source MAC address 211b, and EtherType 211c. A value indicating that the data frame is a data frame conforming to EtherCAT is set in the EtherType 211c.

The Ethernet data 212 includes a plurality of datagrams 220 for each of the plurality of subordinate devices 102. Therefore, the number of datagrams 220 is N, and the plurality of datagrams 220 includes datagrams 220₁ to 220_{N}. In the following description, a datagram 220ₙ indicates a datagram for the subordinate device 102ₙ.

The datagram 220ₙ includes a datagram header 221, setting data 222, and monitor data 223. The datagram header 221 in the datagram 220ₙ includes an address of the subordinate device 102ₙ. The setting data 222 in the datagram 220ₙ is setting data for the subordinate device 102ₙ. The monitor data 223 in the datagram 220ₙ is monitor data acquired in the subordinate device 102ₙ.

Returning to FIG. 4, the subordinate device 102ₙ is configured to control an output thereof according to the setting data 222 in the datagram 220ₙ. In the plasma processing system, the output of the subordinate device 102 is any one of the internal pressure of the chamber 10, the flow rate of the gas output by the flow rate controller 22, the source RF power, which have been described above, and the like.

Each of the subordinate devices 102 includes a first port 102a, a second port 102b, and a communication processor 102c. A data frame transmitted from an upstream side via the communication path 121 is received at the first port 102a and is provided to the communication processor 102c. A data frame provided from the communication processor 102c to the second port 102b is transmitted to a downstream side via the communication path 121. A data frame transmitted from an upstream side via the communication path 122 is received at the second port 102b and is provided to the communication processor 102c. A data frame provided from the communication processor 102c to the first port 102a is transmitted to a downstream side via the communication path 122.

The communication processor 102c may be configured as a circuit such as an integrated circuit. The communication processor 102c may be configured as, for example, an application specific integrated circuit (ASIC) or a field programmable gate array (FPGA).

The communication processor 102c of the subordinate device 102ₙ is configured to extract the setting data 222 from the datagram 220ₙ. When the address in the datagram header 221 is the address of the subordinate device 102ₙ, the communication processor 102c of the subordinate device 102ₙ extracts the setting data 222 from the datagram 220ₙ including the datagram header 221. The subordinate device 102ₙ controls an output thereof according to the setting data 222 extracted by the communication processor 102c. In addition, the communication processor 102c of the subordinate device 102ₙ writes the monitor data acquired in the subordinate device 102ₙ, as the monitor data 223 in the datagram 220ₙ.

The calculation device 103 is configured to obtain updated setting data for each of the plurality of subordinate devices 102 based on the monitor data 223 of each of the plurality of subordinate devices 102 in a data frame received in a preceding communication cycle. The updated setting data for each of the plurality of subordinate devices 102 may be included in a data frame transmitted to the plurality of subordinate devices 102 in a subsequent communication cycle.

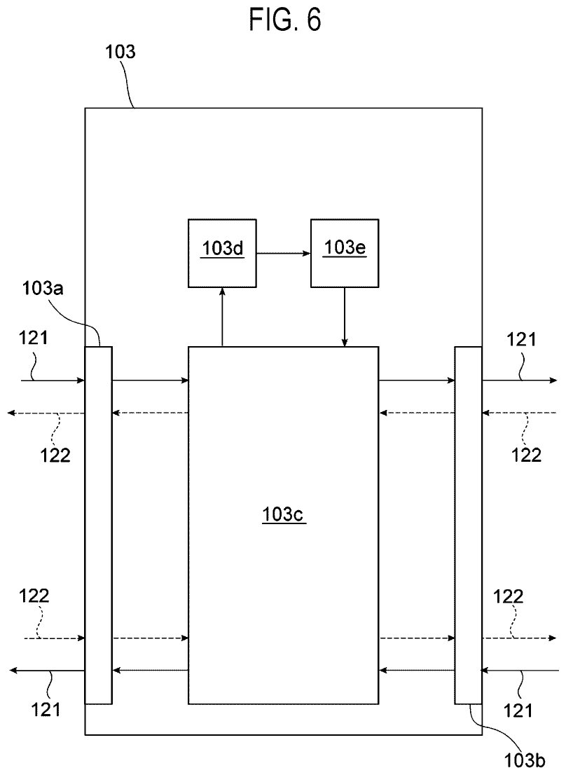

FIG. 6 is a diagram showing a calculation device according to an exemplary embodiment. As shown in FIG. 6, the calculation device 103 includes a first port 103a, a second port 103b, a communication processor 103c, a data analyzer 103d, and a calculator 103e.

A data frame transmitted from the main device 101 to the calculation device 103 via the communication path 121 is received at the first port 103a. A data frame transmitted from the calculation device 103 to the plurality of subordinate devices 102 via the communication path 121 is output from the second port 103b. A data frame transmitted from the plurality of subordinate devices 102 to the calculation device 103 via the communication path 121 is received at the second port 103b. A data frame transmitted from the calculation device 103 to the main device 101 via the communication path 121 is output from the first port 103a.

A data frame transmitted from the main device 101 to the calculation device 103 via the communication path 122 is received at the first port 103a. A data frame transmitted from the calculation device 103 to the plurality of subordinate devices 102 via the communication path 122 is output from the second port 103b. A data frame transmitted from the plurality of subordinate devices 102 to the calculation device 103 via the communication path 122 is received at the second port 103b. A data frame transmitted from the calculation device 103 to the main device 101 via the communication path 122 is output from the first port 103a.

The communication processor 103c may be configured as a circuit such as an integrated circuit. The communication processor 103c may be configured as, for example, an application specific integrated circuit (ASIC) or a field programmable gate array (FPGA).

The communication processor 103c is configured to receive a first data frame 200₁ in a first communication cycle TC1 and transmit a second data frame 200₂ in a second communication cycle TC2. The second communication cycle TC2 is a communication cycle following the first communication cycle TC1. Each of the first data frame 200₁ and the second data frame 200₂ has the same structure as the data frame 200.

The communication processor 103c branches the first data frame 200₁, in which the monitor data is written in each datagram, to the main device 101 and the data analyzer 103d. The communication processor 103c creates the second data frame 200₂, in which the updated setting data 222 for each of the plurality of subordinate devices 102 is included in the corresponding datagram. The communication processor 103c transmits the second data frame 200₂ to the main device 101 and the plurality of subordinate devices 102 in the second communication cycle TC2.

The data analyzer 103d may be configured as a circuit such as an integrated circuit. The communication processor 103c may be configured as, for example, an application specific integrated circuit (ASIC) or a field programmable gate array (FPGA). The data analyzer 103d extracts the monitor data 223 from each of the plurality of datagrams 220 in the first data frame 200₁ and provides the extracted monitor data 223 to the calculator 103e.

The calculator 103e is configured as, for example, a calculation unit such as a CPU. The calculator 103e obtains the updated setting data 222 based on the monitor data 223 extracted by the data analyzer 103d. The updated setting data 222 is written in the corresponding datagram in the second data frame 200₂ by the communication processor 103c. For example, the setting data 222 obtained based on the monitor data 223 extracted from the datagram 220ₙ in the first data frame 200₁ is written in the datagram 220ₙ in the second data frame 200₂.

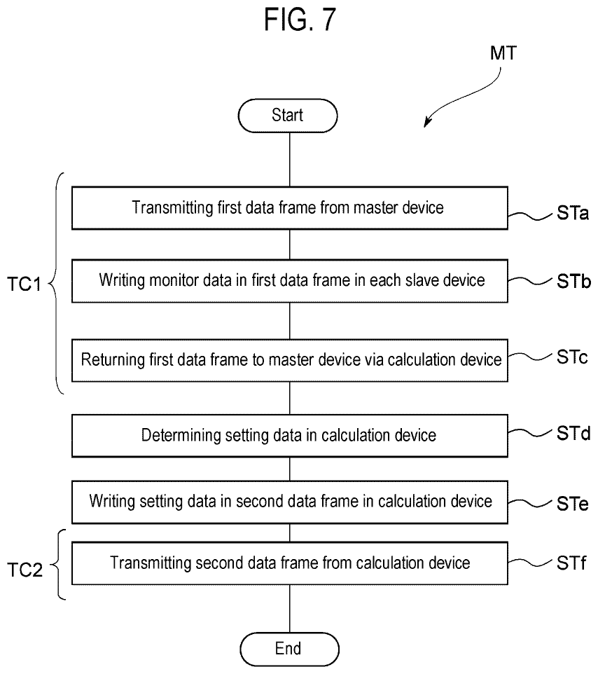

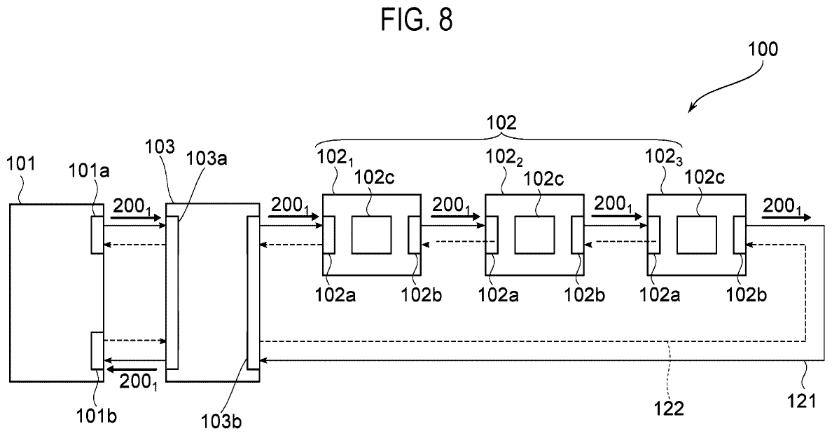

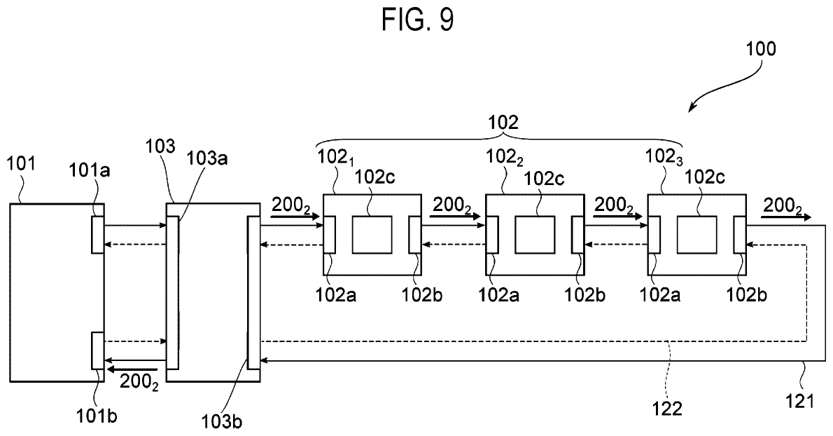

Below, a communication method according to one exemplary embodiment will be described with reference to FIGS. 7 to 9. FIG. 7 is a flowchart of a communication method according to one exemplary embodiment. FIG. 8 is a diagram showing a flow of a first data frame in the communication system according to one exemplary embodiment. FIG. 9 is a diagram showing a flow of a second data frame in the communication system according to one exemplary embodiment. The communication method shown in FIG. 7 (hereinafter referred to as a “method MT”) is performed in the communication system 100.

The method MT starts in step STa. In step STa, the first data frame 200₁ is transmitted from the main device 101 to the plurality of subordinate devices 102. As shown in FIG. 8, the first data frame 200₁ is transmitted from the main device 101 to the plurality of subordinate devices 102 in sequence via the calculation device 103 on the communication path 121.

In subsequent step STb, the plurality of subordinate devices 102 sequentially write the monitor data 223 into the corresponding datagram in the first data frame 200₁. That is, the subordinate device 102ₙ writes the monitor data 223 acquired in the subordinate device 102ₙ into the datagram 220ₙ in the first data frame 200₁. As shown in FIG. 8, the subordinate device 102ₙ transmits the first data frame 200₁ to a downstream side via the communication path 121. In step STb, each of the plurality of subordinate devices 102 may control an output thereof according to the setting data 222 in the corresponding datagram in the first data frame 200₁. That is, the subordinate device 102ₙ may control the output thereof according to the setting data 222 in the datagram 220ₙ in the first data frame 200₁.

In subsequent step STc, as shown in FIG. 8, the first data frame 200₁ is returned to the main device 101 via the calculation device 103. The transmission of the first data frame 200₁ from step STa to step STc is performed in the first communication cycle TC1.

In subsequent step STd, the calculation device 103 obtains updated setting data 222 based on the monitor data 223 in each of the plurality of datagrams in the first data frame 200₁. For example, the calculation device 103 obtains the updated setting data 222 for the subordinate device 102ₙ based on the monitor data 223 in the datagram 220ₙ.

In subsequent step STe, the calculation device 103 writes the updated setting data 222 for the corresponding subordinate device in each of the plurality of datagrams in the second data frame 200₂. That is, the calculation device 103 writes the updated setting data 222 for the corresponding subordinate device 102ₙ in the datagram 220ₙ in the second data frame 200₂. By step STe, the second data frame 200₂ is created.

In subsequent step STf, as shown in FIG. 9, the calculation device 103 transmits the second data frame 200₂ to the plurality of subordinate devices 102. The second data frame 200₂ is transmitted in sequence to the plurality of subordinate devices 102 via the communication path 121 in the second communication cycle TC2. In step STf, the calculation device 103 also transmits the second data frame 200₂ to the main device 101. After step STf, each of the plurality of subordinate devices 102 controls an output thereof according to the setting data 222 in the corresponding datagram in the second data frame 200₂. That is, the subordinate device 102ₙ controls an output thereof according to the setting data 222 in the datagram 220ₙ in the second data frame 200₂.

According to the communication system 100 described above, the setting data 222 is updated not in the main device 101 but in the calculation device 103. Therefore, a calculation load of the main device 101 is reduced.

In addition, according to the communication system 100, collecting monitor data from the plurality of subordinate devices 102 and providing updated setting data to the plurality of subordinate devices 102 are completed in only the first and second communication cycles, i.e., two communication cycles. Therefore, the communication system 100 can collect monitor data from the plurality of subordinate devices 102 and provide updated setting data to the plurality of subordinate devices 102 within a short period of time. Further, in the communication system 100, the only data frames transmitted in the first and second communication cycles are the first data frame 200₁ and the second data frame 200₂. Therefore, the communication system 100 can perform communication, including the collection of monitor data from the plurality of subordinate devices 102 and the provision of updated setting data to the plurality of subordinate devices 102, with a small amount of data.

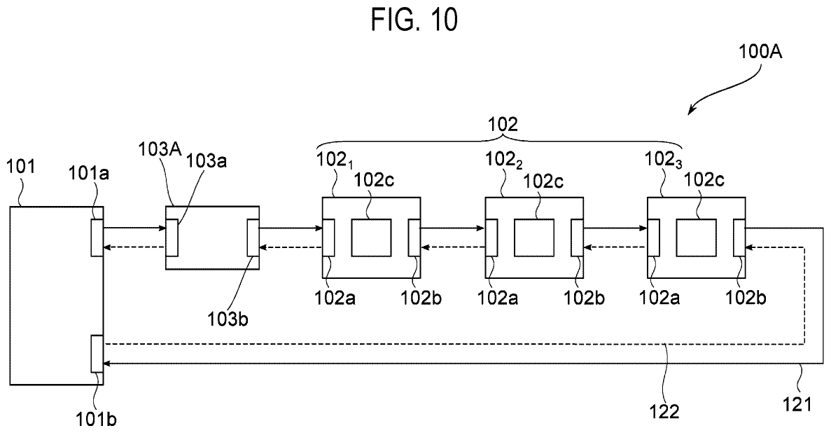

Below, a communication system according to another exemplary embodiment will be described with reference to FIG. 10. FIG. 10 is a diagram showing a communication system according to another exemplary embodiment. The plasma processing system described above may be an example of a communication system 100A shown in FIG. 10. The communication system 100A will be described below in terms of differences between the communication system 100 and the communication system 100A.

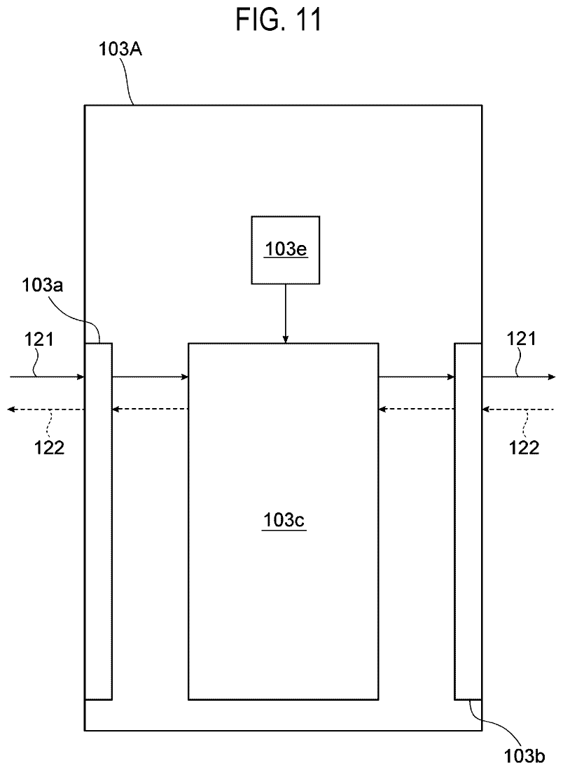

The communication system 100A includes a calculation device 103A instead of the calculation device 103. FIG. 11 is a diagram showing a calculation device according to another exemplary embodiment. As shown in FIG. 11, the calculation device 103A includes a first port 103a, a second port 103b, a communication processor 103c, and a calculator 103e.

A data frame transmitted from the main device 101 to the calculation device 103A via the communication path 121 is received at the first port 103a. A data frame transmitted from the calculation device 103A to the plurality of subordinate devices 102 via the communication path 121 is output from the second port 103b. The data frame output from the second port 103b to the communication path 121 is returned to the second port 101b of the main device 101 via the plurality of subordinate devices 102.

A data frame transmitted from the main device 101 to the plurality of subordinate devices 102 via the communication path 122 is received at the second port 103b of the calculation device 103A via the plurality of subordinate devices 102. A data frame transmitted from the calculation device 103A to the main device 101 via the communication path 122 is output from the first port 103a.

The communication processor 103c of the calculation device 103A is configured to receive a second data frame 202 in the second communication cycle TC2 and transmit a third data frame 203 in a third communication cycle TC3.

The communication processor 103c of the calculation device 103A outputs the second data frame 202 to the calculator 103e. The communication processor 103c of the calculation device 103A creates the third data frame 203 including updated setting data 222 for each of the plurality of subordinate devices 102, and transmits the created third data frame 203 to the main device 101 in the third communication cycle TC3.

The calculator 103e of the calculation device 103A obtains the updated setting data 222 based on the monitor data 223 of each of the plurality of subordinate devices 102 in the second data frame 202. The updated setting data 222 is written in the third data frame 203 by the communication processor 103c.

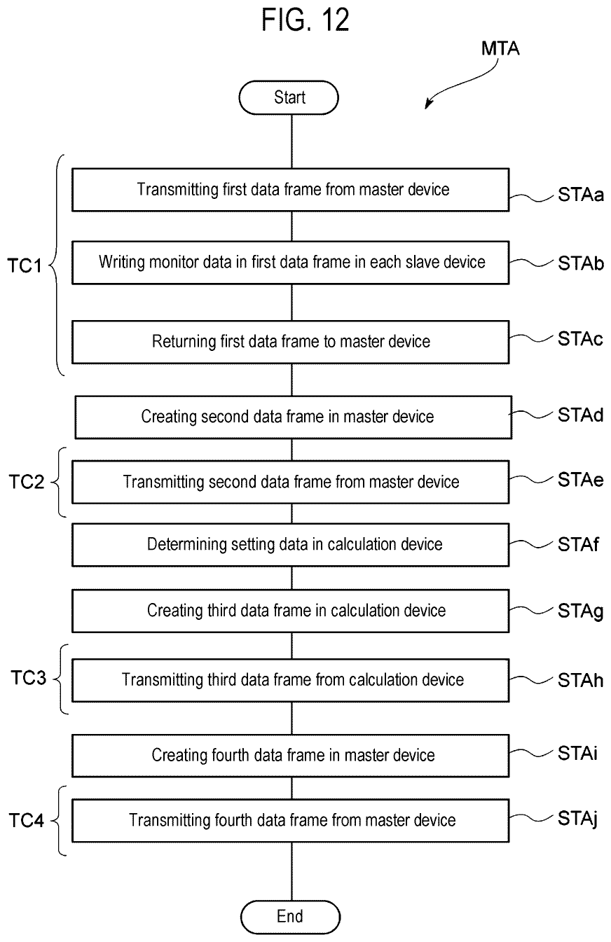

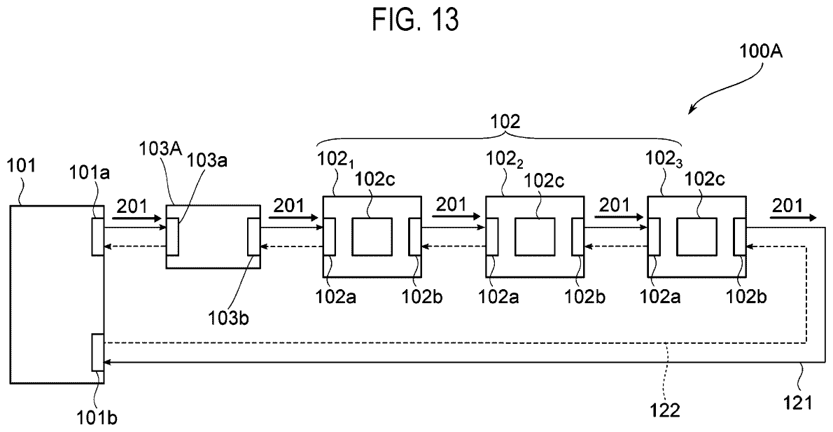

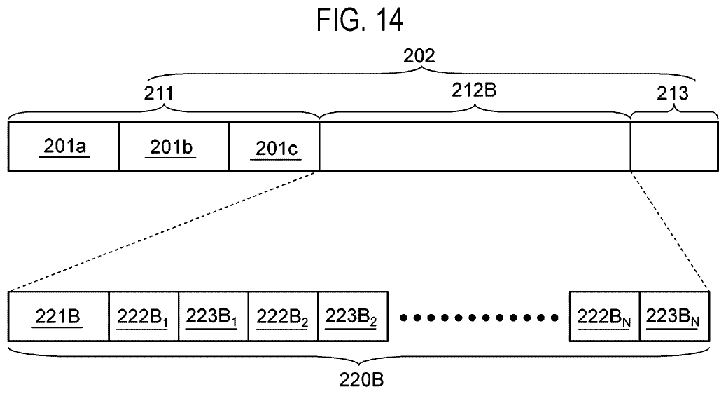

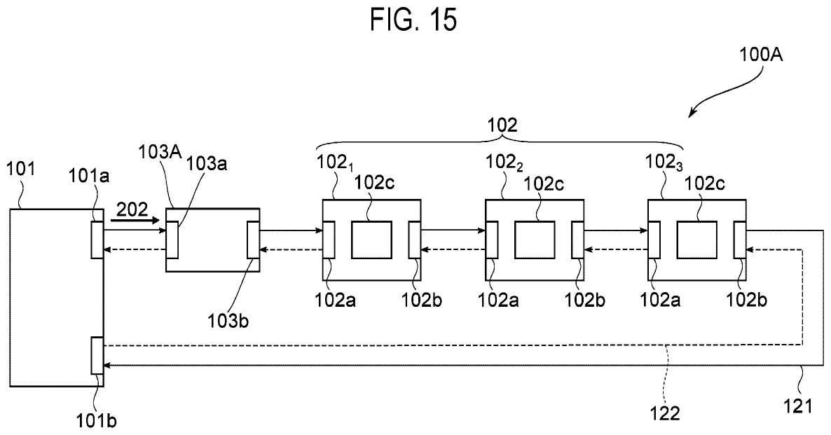

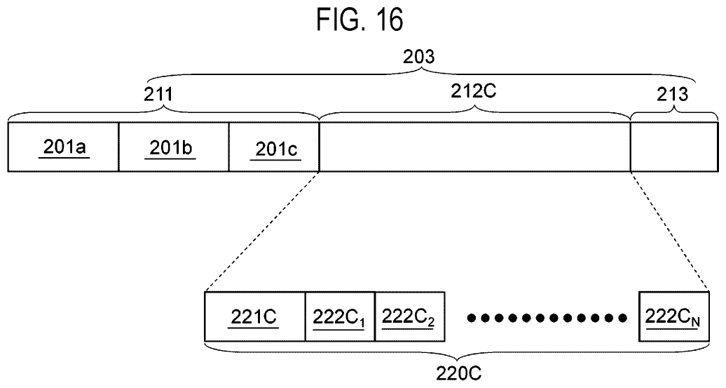

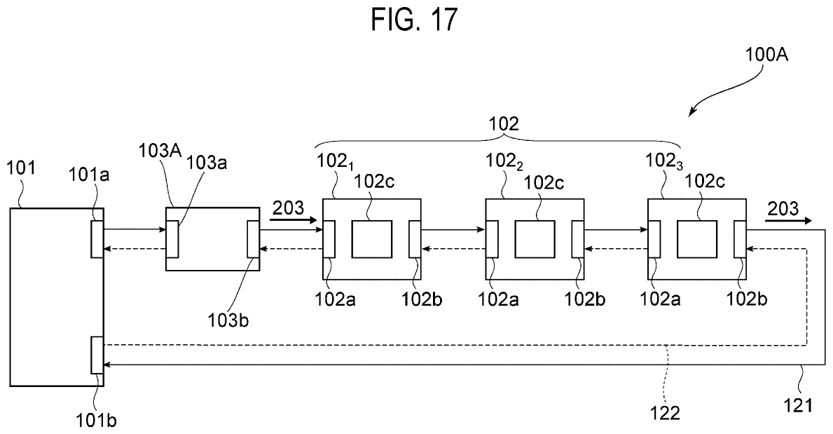

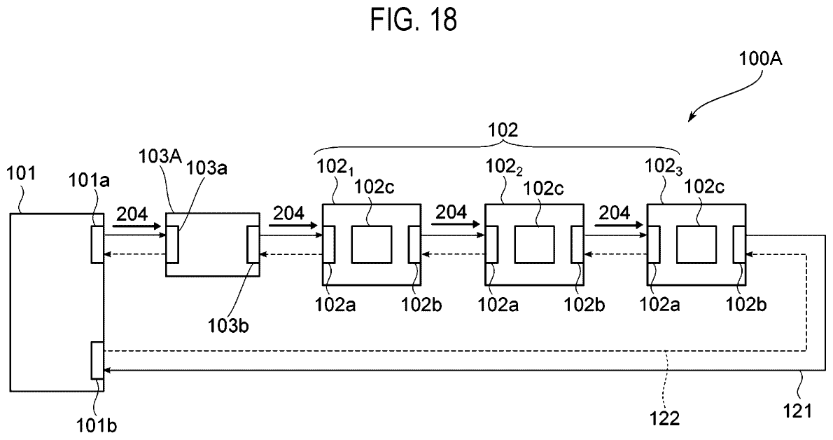

A communication method according to another exemplary embodiment will be described below with reference to FIGS. 12 to 18. FIG. 12 is a flowchart of a communication method according to another exemplary embodiment. FIG. 13 is a diagram showing a flow of a first data frame in the communication system according to another exemplary embodiment. FIG. 14 is a diagram showing a second data frame used in the communication system according to another exemplary embodiment. FIG. 15 is a diagram showing a flow of a second data frame in the communication system according to another exemplary embodiment. FIG. 16 is a diagram showing a third data frame used in the communication system according to another exemplary embodiment. FIG. 17 is a diagram showing a flow of a third data frame in the communication system according to another exemplary embodiment. FIG. 18 is a diagram showing a flow of a fourth data frame in the communication system according to another exemplary embodiment. The communication method shown in FIG. 12 (hereinafter referred to as a “method MTA”) is performed in the communication system 100A.

The method MTA starts in step STAa. In step STAa, a first data frame 201 is transmitted from the main device 101 to the plurality of subordinate devices 102. The first data frame 201 is a data frame similar to the first data frame 200₁ transmitted in the communication system 100. As shown in FIG. 13, the first data frame 201 is transmitted from the main device 101 to the plurality of subordinate devices 102 in sequence via the calculation device 103A on the communication path 121.

In subsequent step STAb, the plurality of subordinate devices 102 write the monitor data 223 in sequence into the corresponding datagrams in the first data frame 201. That is, the subordinate device 102ₙ writes the monitor data 223 acquired in the subordinate device 102ₙ into the datagram 220ₙ in the first data frame 201. As shown in FIG. 13, the subordinate device 102ₙ transmits the first data frame 201 to a downstream side via the communication path 121. In addition, in step STAb, each of the plurality of subordinate devices 102 may control an output thereof according to the setting data 222 in the corresponding datagram in the first data frame 201.

In subsequent step STAc, as shown in FIG. 13, the first data frame 201 is returned to the main device 101. The transmission of the first data frame 200₁ from step STAa to step STAc is performed in the first communication cycle TC1.

In subsequent step STAd, the main device 101 creates a second data frame 202 from the monitor data 223 in each of the plurality of datagrams 220 of the first data frame 201.

The second data frame 202 is a data frame conforming to EtherCAT. As shown in FIG. 14, the second data frame 202 includes an Ethernet header 211, Ethernet data 212B, and a frame check sequence 213.

The Ethernet data 212B includes a datagram 220B. The datagram 220B includes a datagram header 221B, and monitor data 222B₁, monitor data 223B₁, . . . , monitor data 222B_{N}, and monitor data 223B_{N}. The datagram header 221B includes an address of the calculation device 103A. A monitor data 223Bₙ is monitor data in the second data frame 202 acquired by the subordinate device 102ₙ.

In subsequent step STAe, as shown in FIG. 15, the main device 101 transmits the second data frame 202 to the calculation device 103A. The second data frame 202 is transmitted via the communication path 121 in the second communication cycle TC2.

In subsequent step STAf, the calculation device 103A obtains updated setting data 222 based on the monitor data in the second data frame 202. For example, the calculation device 103A obtains updated setting data 222ₙ for the subordinate device 102ₙ based on the monitor data 223Bₙ.

In subsequent step STAg, the calculation device 103A creates a third data frame 203 including the updated setting data 222 for each of the plurality of subordinate devices 102.

The third data frame 203 is a data frame conforming to EtherCAT. As shown in FIG. 16, the third data frame 203 includes an Ethernet header 211, Ethernet data 212C, and a frame check sequence 213.

The Ethernet data 212C includes a datagram 220C. The datagram 220C includes a datagram header 221C and setting data 222C₁, . . . , setting data 222C_{N}. The datagram header 221C includes an address of the main device 101. Setting data 222Cₙ is updated setting data for the subordinate device 102ₙ.

In subsequent step STAh, as shown in FIG. 17, the calculation device 103A transmits the third data frame 203 to the main device 101. The third data frame 203 is transmitted via the communication path 121 in the third communication cycle TC3.

In subsequent step STAi, the main device 101 creates a fourth data frame 204 that includes the setting data 222C₁, . . . , setting data 222C_{N} in the third data frame 203 in a plurality of datagrams of the fourth data frame 204. The fourth data frame 204 is a data frame similar to the second data frame 200₂.

In subsequent step STAj, as shown in FIG. 18, the main device 101 transmits the fourth data frame 204 to the plurality of subordinate devices 102. The fourth data frame 204 is transmitted to the plurality of subordinate devices 102 in sequence via the communication path 121 in a fourth communication cycle TC4. After step STAj, each of the plurality of subordinate devices 102 controls an output thereof according to the setting data 222 in the corresponding datagram in the fourth data frame 204.

In the communication system 100A described above, the setting data 222 is updated not in the main device 101 but in the calculation device 103A. Therefore, a calculation load of the main device 101 is reduced.

In addition, in the communication system 100A, collecting monitor data from the plurality of subordinate devices 102 and providing updated setting data to the plurality of subordinate devices 102 are completed in the first to fourth communication cycles, i.e., four communication cycles. Thus, the communication system 100 can complete the collection of monitor data from the plurality of subordinate devices 102 and the provision of updated setting data to the plurality of subordinate devices 102 in fewer cycles than the communication system 100A. Therefore, the communication system 100 can complete the collection of monitor data from the plurality of subordinate devices 102 and the provision of updated setting data to the plurality of subordinate devices 102 within a shorter period of time than the communication system 100A. In addition, in the communication system 100A, the first to fourth data frames are transmitted in the first to fourth communication cycles, respectively. On the other hand, in the communication system 100, the only data frames transmitted are the first data frame 200₁ and the second data frame 200₂. Therefore, the communication system 100 can perform communication, including the collection of monitor data from the plurality of subordinate devices 102 and the provision of updated setting data to the plurality of subordinate devices 102, with a smaller amount of data than the communication system 100A.

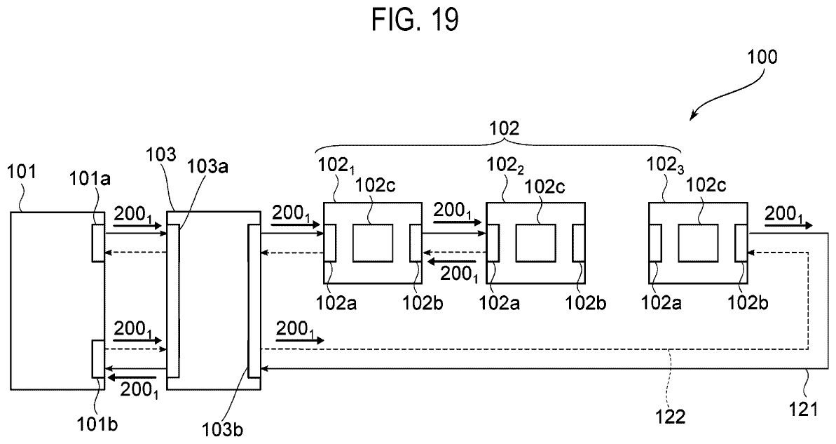

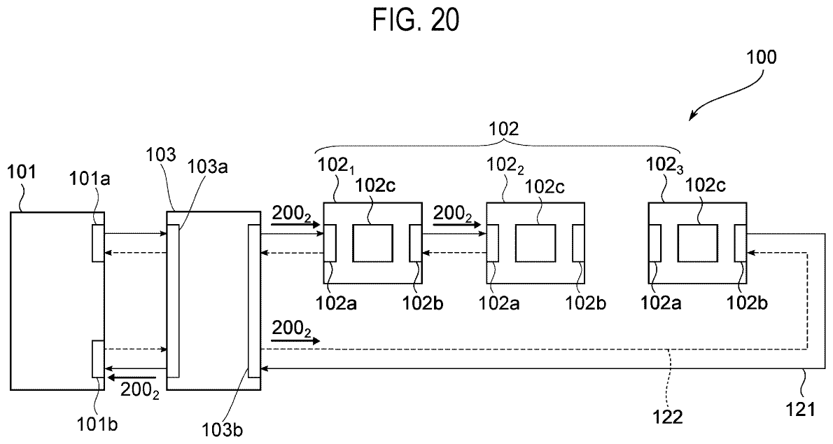

FIG. 19 is a diagram showing another flow of the first data frame in the communication system according to the exemplary embodiment. FIG. 20 is a diagram showing another flow of the second data frame in the communication system according to the exemplary embodiment. The communication system 100 may transmit the first data frame 200₁ and the second data frame 200₂ via the communication path 121 when no disconnection occurs between two of the plurality of subordinate devices 102.

On the other hand, as shown in FIGS. 19 and 20, when a disconnection occurs between two of the plurality of subordinate devices 102, the communication system 100 may transmit the first data frame 200₁ and the second data frame 200₂ via both the communication path 121 and the communication path 122.

As shown in FIG. 19, the main device 101 transmits the first data frame 200₁ from the first port 101a via the communication path 121, to all the subordinate devices with which communication with the first port 101a is maintained. The first data frame 200₁ is returned to the calculation device 103 and the first port 101a of the main device 101 via the communication path 122, from the most downstream-side subordinate device among all the subordinate devices with which communication with the first port 101a is maintained.

In addition, as shown in FIG. 19, the main device 101 transmits the first data frame 200₁ from the second port 101b via the communication path 122, to all the subordinate devices with which communication with the second port 101b is maintained. The first data frame 200₁ is returned to the calculation device 103 and the second port 101b of the main device 101 via the communication path 121, from the most downstream-side subordinate device among all the subordinate devices with which communication with the second port 101b is maintained.

In addition, as shown in FIG. 20, the calculation device 103 transmits the second data frame 200₂ from the second port 103b via the communication path 121, to all the subordinate devices with which communication with the second port 103b is maintained. In addition, as shown in FIG. 20, the calculation device 103 transmits the second data frame 200₂ from the second port 103b via the communication path 122, to all the subordinate devices with which communication with the second port 103b is maintained.

In the example shown in FIGS. 19 and 20, the communication system 100 can collect monitor data from the plurality of subordinate devices 102 and provide updated setting data to the plurality of subordinate devices 102 even when a disconnection occurs between two subordinate devices.

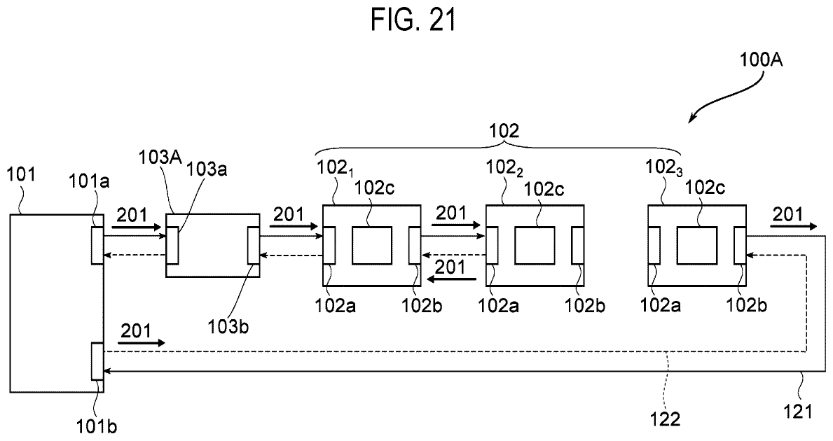

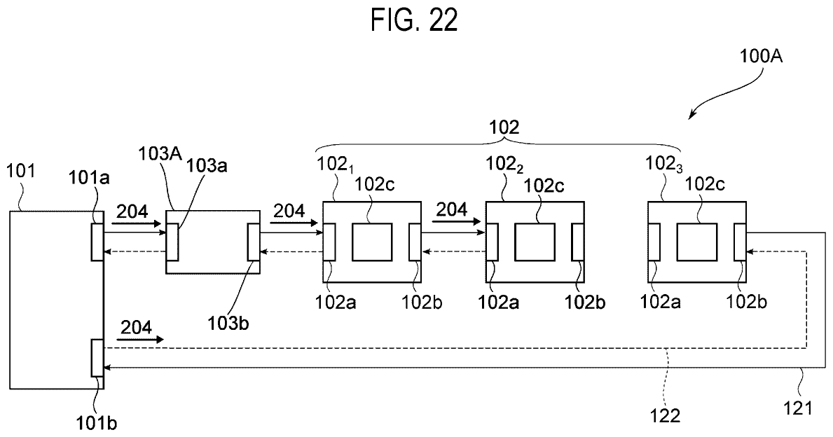

FIG. 21 is a diagram showing another flow of the first data frame in the communication system according to the another exemplary embodiment. FIG. 22 is a diagram showing another flow of the fourth data frame in the communication system according to the another exemplary embodiment. The communication system 100A may transmit the first data frame 201 and the fourth data frame 204 via the communication path 121 when no disconnection occurs between two of the plurality of subordinate devices 102.

On the other hand, as shown in FIGS. 21 and 22, when a disconnection occurs between two of the plurality of subordinate devices 102, the communication system 100A may transmit the first data frame 201 and the fourth data frame 204 via both the communication path 121 and the communication path 122.

As shown in FIG. 21, the main device 101 transmits the first data frame 201 from the first port 101a via the communication path 121, to all the subordinate devices with which communication with the first port 101a is maintained. The first data frame 201 is returned to the first port 101a of the main device 101 via the communication path 122, from the most downstream-side subordinate device among all the subordinate devices with which communication with the first port 101a is maintained.

In addition, as shown in FIG. 21, the main device 101 transmits the first data frame 201 from the second port 101b via the communication path 122, to all the subordinate devices with which communication with the second port 101b is maintained. The first data frame 201 is returned to the second port 101b of the main device 101 via the communication path 121, from the most downstream-side subordinate device among all the subordinate devices with which communication with the second port 101b is maintained.

In addition, as shown in FIG. 22, the main device 101 transmits the fourth data frame 204 from the first port 101a via the communication path 121, to all the subordinate devices with which communication with the first port 101a is maintained. In addition, the main device 101 transmits the fourth data frame 204 from the second port 103b via the communication path 122, to all the subordinate devices with which communication with the second port 101b is maintained.

In the example shown in FIGS. 21 and 22, the communication system 100A can collect monitor data from the plurality of subordinate devices 102 and provide updated setting data to the plurality of subordinate devices 102 even when a disconnection occurs between two subordinate devices.

Although various exemplary embodiments have been described above, various additions, omissions, substitutions, and modifications may be made without being limited to the exemplary embodiments described above. In addition, other embodiments can be formed by combining elements in different embodiments.

For example, each of the communication systems 100 and 100A may be a substrate processing system other than a plasma processing system, as long as it uses the data frame and communication method described above. In addition, each of the communication systems 100 and 100A may be an industrial system other than a substrate processing system, as long as it uses the data frame and communication method described above.

In addition, the calculation device in the various embodiments described above may have a communication function as a subordinate device (secondary device or slave device) conforming to EtherCAT. In this case, the plurality of datagrams in the data frame communicated between the main device and the calculation device include a datagram for the calculation device. The datagram for the calculation device includes a datagram header including an address of the calculation device, monitor data, and setting data. The setting data in the datagram for the calculation device may include data relating to setting conditions for operations of the calculation device. The monitor data in the datagram for the calculation device may include data relating to a status of the calculation device. In addition, the calculation device in the various embodiments described above may not have such a communication function as a subordinate device. That is, the plurality of datagrams in the data frame may not include a datagram for the calculation device.

Here, various exemplary embodiments included in the present disclosure will be described in [E1] to [E17] below.

### [E1]

A communication system including:
a main device;
a plurality of subordinate devices communicatively connected to the main device; and
a calculation device communicatively connected to the main device and the plurality of subordinate devices,
wherein a data frame transmitted to the plurality of subordinate devices includes a plurality of datagrams for each of the plurality of subordinate devices, each of the plurality of datagrams including setting data for a corresponding one of the plurality of subordinate devices and monitor data to be written in the corresponding one of the plurality of subordinate devices, and
wherein the calculation device is configured to obtain, based on the monitor data for each of the plurality of subordinate devices in the data frame received in a preceding communication cycle, updated setting data for each of the plurality of datagrams in the data frame transmitted to the plurality of subordinate devices in a subsequent communication cycle.

### [E2]

The communication system of E1, wherein the calculation device is further configured to:
create, based on the monitor data in each of the plurality of datagrams of a first data frame received in a first communication cycle, a second data frame including the plurality of datagrams, each including the updated setting data; and
transmit the second data frame to the plurality of subordinate devices and the main device in a second communication cycle following the first communication cycle.

### [E3]

The communication system of E2, further including:
a main communication path that returns from a first port of the main device to a second port of the main device via the calculation device and the plurality of subordinate devices; and
a backup communication path that returns from the second port to the first port via the calculation device and the plurality of subordinate devices,
wherein the communication system is configured to:
   transmit the first data frame and the second data frame via the main communication path when no disconnection occurs between two of the plurality of subordinate devices; and
   transmit the first data frame and the second data frame via both the main communication path and the backup communication path when a disconnection occurs between two of the plurality of subordinate devices.

### [E4]

The communication system of E2 or E3, wherein the calculation device includes:
a communication processor configured to receive the first data frame and transmit the second data frame;
a datagram analyzer configured to acquire the monitor data in each of the plurality of datagrams in the first data frame; and
a calculator configured to obtain the updated setting data based on the monitor data acquired by the datagram analyzer.

### [E5]

The communication system of E1, wherein the main device is configured to transmit a first data frame and receive the first data frame including the monitor data written in the corresponding one of the plurality of subordinate devices in each of the plurality of datagrams, in a first communication cycle,
wherein the main device is further configured to create a second data frame including the monitor data in each of the plurality of datagrams of the first data frame and transmit the second data frame to the calculation device in a second communication cycle,
wherein the calculation device is further configured to create a third data frame including the updated setting data for each of the plurality of subordinate devices based on the second data frame and transmit the third data frame to the main device in a third communication cycle, and
wherein the main device is further configured to create a fourth data frame including the updated setting data for each of the plurality of subordinate devices in the third data frame in a corresponding datagram of the plurality of datagrams and transmit the fourth data frame to the plurality of subordinate devices in a fourth communication cycle.

### [E6]

The communication system of E5, further including:
a main communication path that returns from a first port of the main device to a second port of the main device via the calculation device and the plurality of subordinate devices; and
a backup communication path that returns from the second port to the first port via the calculation device and the plurality of subordinate devices,
wherein the communication system is configured to:
   transmit the first data frame, the second data frame, the third data frame, and the fourth data frame via the main communication path when no disconnection occurs between two of the plurality of subordinate devices; and
   transmit the first data frame, the second data frame, the third data frame, and the fourth data frame via both the main communication path and the backup communication path when a disconnection occurs between two of the plurality of subordinate devices and no disconnection occurs in the main communication path.

### [E7]

The communication system of E5 or E6, wherein the calculation device includes:
a communication processor configured to receive the second data frame and transmit the third data frame; and
a calculator configured to obtain the updated setting data for each of the plurality of subordinate devices based on the second data frame.

### [E8]

The communication system of any one of E1 to E7, wherein the communication system is a substrate processing system including:
a process chamber; and
a substrate support configured to support a substrate in the chamber.

### [E9]

The communication system of E8, wherein the plurality of subordinate devices include:
a pressure controller configured to control an internal pressure of the chamber according to the setting data; and
a pressure sensor configured to acquire a measured value of the internal pressure of the chamber as the monitor data.

### [E10]

The communication system of E8 or E9, wherein the plurality of subordinate devices include a flow rate controller configured to control a flow rate of a gas supplied into the chamber according to the setting data and acquire a measured value of the flow rate of the gas as the monitor data.

### [E11]

The communication system of any one of E8 to E10, wherein the communication system is a plasma processing system, and
wherein the plurality of subordinate devices include a radio frequency (RF) generator configured to set radio frequency power used to generate plasma from a gas in the chamber according to the setting data and acquire a state value of the radio frequency power as the monitor data.

### [E12]

The communication system of any one of E1 to E11, wherein the datagrams conform to EtherCAT (registered trademark).

### [E13]

A calculation device for use in a communication system, wherein the calculation device is communicatively connected to a main device and a plurality of subordinate devices, and
wherein the calculation device includes:
   a communication processor configured to receive a first data frame in a first communication cycle and transmit a second data frame in a second communication cycle following the first communication cycle, wherein each of the first data frame and the second data frame includes a plurality of datagrams for each of the plurality of subordinate devices, and each of the plurality of datagrams includes setting data for a corresponding one of the plurality of subordinate devices and monitor data to be written in the corresponding one of the plurality of subordinate devices;
   a datagram analyzer configured to acquire the monitor data in each of the plurality of datagrams of the first data frame; and
   a calculator configured to obtain updated setting data for each of the plurality of datagrams in the second data frame to be transmitted to the plurality of subordinate devices, based on the monitor data acquired by the datagram analyzer from the first data frame.

### [E14]

A calculation device for use in a communication system, wherein the calculation device being communicatively connected to a main device and a plurality of subordinate devices, and
wherein the calculation device includes:
   a communication processor configured to receive and transmit a data frame; and
   a calculator configured to obtain, based on monitor data for each of the plurality of subordinate devices in a data frame transmitted from the main device in a preceding communication cycle, updated setting data in each of a plurality of datagrams for each of the plurality of subordinate devices in a data frame transmitted to the plurality of subordinate devices in a subsequent communication cycle.

### [E15]

A communication method including:
(a) writing, in each of a plurality of subordinate devices, monitor data into a corresponding one of a plurality of datagrams of a data frame, wherein the data frame includes the plurality of datagrams for each of the plurality of subordinate devices, and each of the plurality of datagrams includes setting data and the monitor data for a corresponding one of the plurality of subordinate devices; and
(b) obtaining, in a calculation device communicatively connected to a main device and the plurality of subordinate devices, updated setting data for each of the plurality of datagrams in the data frame to be transmitted to the plurality of subordinate devices, based on the monitor data in each of the plurality of datagrams of the data frame obtained in (a).

### [E16]

The communication method of E15, wherein the data frame obtained in (a) is a first data frame transmitted in a first communication cycle, and
wherein the communication method further includes:
   (c) creating, in the calculation device, a second data frame including the plurality of datagrams, each including the updated setting data; and
   (d) transmitting the second data frame from the calculation device to the plurality of subordinate devices.

### [E17]

The communication method of E15, wherein the data frame obtained in (a) is a first data frame transmitted in a first communication cycle, and
wherein the communication method further includes:
   (c) receiving, in a main device, the first data frame in which the monitor data is written into each of the plurality of datagrams;
   (d) generating, in the main device, a second data frame including the monitor data in each of the plurality of datagrams of the first data frame;
   (e) transmitting the second data frame from the main device to the calculation device in a second communication cycle;
   (f) creating, in the calculation device, a third data frame including the updated setting data for each of the plurality of subordinate devices;
   (g) transmitting the third data frame from the calculation device to the main device in a third communication cycle;
   (h) creating, in the main device, a fourth data frame including the updated setting data for each of the plurality of subordinate devices in the third data frame in a corresponding one of the plurality of datagrams; and
   (i) transmitting the fourth data frame from the main device to the plurality of subordinate devices in a fourth communication cycle.

According to one exemplary embodiment, it is possible to reduce a calculation load of a main device in a communication system.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A communication system comprising:
a main device;
a plurality of subordinate devices communicatively connected to the main device; and
a calculation device communicatively connected to the main device and the plurality of subordinate devices,
wherein a data frame transmitted to the plurality of subordinate devices includes a plurality of datagrams for each of the plurality of subordinate devices, each of the plurality of datagrams including setting data for a corresponding one of the plurality of subordinate devices and monitor data to be written in the corresponding one of the plurality of subordinate devices, and
wherein the calculation device is configured to obtain, based on the monitor data for each of the plurality of subordinate devices in the data frame received in a preceding communication cycle, updated setting data for each of the plurality of datagrams in the data frame transmitted to the plurality of subordinate devices in a subsequent communication cycle.

2. The communication system of claim 1, wherein the calculation device is further configured to:
create, based on the monitor data in each of the plurality of datagrams of a first data frame received in a first communication cycle, a second data frame including the plurality of datagrams, each including the updated setting data; and
transmit the second data frame to the plurality of subordinate devices and the main device in a second communication cycle following the first communication cycle.

3. The communication system of claim 2, further comprising:
a main communication path that returns from a first port of the main device to a second port of the main device via the calculation device and the plurality of subordinate devices; and
a backup communication path that returns from the second port to the first port via the calculation device and the plurality of subordinate devices,
wherein the communication system is configured to:
transmit the first data frame and the second data frame via the main communication path when no disconnection occurs between two of the plurality of subordinate devices; and
transmit the first data frame and the second data frame via both the main communication path and the backup communication path when a disconnection occurs between two of the plurality of subordinate devices.

4. The communication system of claim 2, wherein the calculation device includes:
a communication processor configured to receive the first data frame and transmit the second data frame;
a datagram analyzer configured to acquire the monitor data in each of the plurality of datagrams in the first data frame; and
a calculator configured to obtain the updated setting data based on the monitor data acquired by the datagram analyzer.

5. The communication system of claim 1, wherein the main device is configured to transmit a first data frame and receive the first data frame including the monitor data written in the corresponding one of the plurality of subordinate devices in each of the plurality of datagrams, in a first communication cycle,
wherein the main device is further configured to create a second data frame including the monitor data in each of the plurality of datagrams of the first data frame, and transmit the second data frame to the calculation device in a second communication cycle,
wherein the calculation device is further configured to create a third data frame including the updated setting data for each of the plurality of subordinate devices based on the second data frame, and transmit the third data frame to the main device in a third communication cycle, and
wherein the main device is further configured to create a fourth data frame including the updated setting data for each of the plurality of subordinate devices in the third data frame in a corresponding datagram of the plurality of datagrams, and transmit the fourth data frame to the plurality of subordinate devices in a fourth communication cycle.

6. The communication system of claim 5, further comprising:
a main communication path that returns from a first port of the main device to a second port of the main device via the calculation device and the plurality of subordinate devices; and
a backup communication path that returns from the second port to the first port via the calculation device and the plurality of subordinate devices,
wherein the communication system is configured to:
transmit the first data frame, the second data frame, the third data frame, and the fourth data frame via the main communication path when no disconnection occurs between two of the plurality of subordinate devices; and
transmit the first data frame, the second data frame, the third data frame, and the fourth data frame via both the main communication path and the backup communication path when a disconnection occurs between two of the plurality of subordinate devices and no disconnection occurs in the main communication path.

7. The communication system of claim 5, wherein the calculation device includes:
a communication processor configured to receive the second data frame and transmit the third data frame; and
a calculator configured to obtain the updated setting data for each of the plurality of subordinate devices based on the second data frame.

8. The communication system of claim 1, wherein the communication system is a substrate processing system including:
a process chamber; and
a substrate support configured to support a substrate in the chamber.

9. The communication system of claim 8, wherein the plurality of subordinate devices include:
a pressure controller configured to control an internal pressure of the chamber according to the setting data; and
a pressure sensor configured to acquire a measured value of the internal pressure of the chamber as the monitor data.

10. The communication system of claim 8, wherein the plurality of subordinate devices include a flow rate controller configured to control a flow rate of a gas supplied into the chamber according to the setting data and acquire a measured value of the flow rate of the gas as the monitor data.

11. The communication system of claim 8, wherein the communication system is a plasma processing system, and
wherein the plurality of subordinate devices include a radio frequency (RF) generator configured to set radio frequency power used to generate plasma from a gas in the chamber according to the setting data and acquire a state value of the radio frequency power as the monitor data.

12. The communication system of claim 1, wherein the datagrams conform to EtherCAT (registered trademark).

13. A calculation device for use in a communication system, wherein the calculation device is communicatively connected to a main device and a plurality of subordinate devices, and
wherein the calculation device comprises:
a communication processor configured to receive a first data frame in a first communication cycle and transmit a second data frame in a second communication cycle following the first communication cycle, wherein each of the first data frame and the second data frame includes a plurality of datagrams for each of the plurality of subordinate devices, and each of the plurality of datagrams includes setting data for a corresponding one of the plurality of subordinate devices and monitor data to be written in the corresponding one of the plurality of subordinate devices;
a datagram analyzer configured to acquire the monitor data in each of the plurality of datagrams of the first data frame; and
a calculator configured to obtain updated setting data for each of the plurality of datagrams in the second data frame to be transmitted to the plurality of subordinate devices, based on the monitor data acquired by the datagram analyzer from the first data frame.

14. A calculation device for use in a communication system, wherein the calculation device is communicatively connected to a main device and a plurality of subordinate devices, and
wherein the calculation device comprises:
a communication processor configured to receive and transmit a data frame; and
a calculator configured to obtain, based on monitor data for each of the plurality of subordinate devices in a data frame transmitted from the main device in a preceding communication cycle, updated setting data in each of a plurality of datagrams for each of the plurality of subordinate devices in a data frame transmitted to the plurality of subordinate devices in a subsequent communication cycle.

15. A communication method comprising:
(a) writing, in each of a plurality of subordinate devices, monitor data into a corresponding one of a plurality of datagrams of a data frame, wherein the data frame includes the plurality of datagrams for each of the plurality of subordinate devices, and each of the plurality of datagrams includes setting data and the monitor data for a corresponding one of the plurality of subordinate devices; and
(b) obtaining, in a calculation device communicatively connected to a main device and the plurality of subordinate devices, updated setting data for each of the plurality of datagrams in the data frame to be transmitted to the plurality of subordinate devices, based on the monitor data in each of the plurality of datagrams of the data frame obtained in (a).

16. The communication method of claim 15, wherein the data frame obtained in (a) is a first data frame transmitted in a first communication cycle, and
wherein the communication method further comprises:
(c) creating, in the calculation device, a second data frame including the plurality of datagrams, each including the updated setting data; and
(d) transmitting the second data frame from the calculation device to the plurality of subordinate devices.

17. The communication method of claim 15, wherein the data frame obtained in (a) is a first data frame transmitted in a first communication cycle, and
wherein the communication method further comprises:
(c) receiving, in a main device, the first data frame in which the monitor data is written into each of the plurality of datagrams;
(d) generating, in the main device, a second data frame including the monitor data in each of the plurality of datagrams of the first data frame;
(e) transmitting the second data frame from the main device to the calculation device in a second communication cycle;
(f) creating, in the calculation device, a third data frame including the updated setting data for each of the plurality of subordinate devices;
(g) transmitting the third data frame from the calculation device to the main device in a third communication cycle;
(h) creating, in the main device, a fourth data frame including the updated setting data for each of the plurality of subordinate devices in the third data frame in a corresponding one of the plurality of datagrams; and
(i) transmitting the fourth data frame from the main device to the plurality of subordinate devices in a fourth communication cycle.
